(19) United States
(12) Patent Application Publication
(10) Pub. No.: US 2025/0299975 A1
(43) Pub. Date: Sep. 25, 2025

(54) APPARATUS OF PROCESSING SUBSTRATE AND METHOD THEREOF

(71) Applicant: SEMES CO., LTD., Cheonan-si (KR)

(72) Inventors: Sang Min LEE, Seoul (KR); Jong Doo LEE, Cheonan-si (KR); Ju Yeon SONG, Sokcho-si (KR)

(73) Assignee: SEMES CO., LTD., Cheonan-si (KR)

(21) Appl. No.: 19/087,986

(22) Filed: Mar. 24, 2025

(30) Foreign Application Priority Data
Mar. 22, 2024 (KR) 10-2024-0039958

(51) Int. Cl. H01L 21/67

(52) U.S. Cl. CPC H01L 21/67017

(57) ABSTRACT

The present disclosure relates to an apparatus of processing a substrate and a method thereof. The apparatus of processing a substrate according to an embodiment of the present disclosure may include: a housing having an internal space; a process chamber disposed in the internal space and defining a processing space in which a substrate is processed-the process chamber including a first chamber body of which a relative position is fixed with respect to the housing and a second chamber body defining the processing chamber by being combined with the first chamber body; an elevation unit moving the second chamber body with respect to the first chamber body such that the processing space can be switched between a sealed state and an open state; a damping unit coupled to the first chamber body and absorbing shock that is applied to the first chamber body when relative movement is generated between the first chamber body and the second chamber body; and a particle removal unit removing particles produced at the damping unit.

### CROSS-REFERENCE TO RELATED APPLICATIONS

This application claims priority to and the benefit of Korean Patent Application No. 10-2024-0039958 filed in the Korean Intellectual Property Office on Mar. 22, 2024, the entire contents of which are incorporated herein by reference.

### TECHNICAL FIELD

The present disclosure relates to an apparatus of processing a substrate and a method thereof, particularly, to an apparatus of processing a substrate that uses supercritical fluid, and a method thereof.

### BACKGROUND ART

In order to manufacture a semiconductor device, a desired pattern is formed on a substrate such as a wafer through various processes such as photolithography, etching, ashing, ion implantation, and thin film deposition. Various processing solutions and processing gases are used in each of the processes, and particles and process byproducts are produced during the processes. A cleaning process is performed before and after these processes to remove particles and process byproducts from a substrate.

The cleaning process cleans a substrate by supplying a cleaning solution to the substrate. Thereafter, a drying process that dries substrates to remove the cleaning solution remaining on the substrate is performed. As an example of the drying process, a supercritical drying process that removes an organic solvent remaining on a substrate in a processing chamber by supplying a drying gas in a supercritical state (e.g., carbon dioxide) to the substrate is used.

The supercritical process opens a drying chamber, loads a substrate into the open drying chamber, closes and then clamps the chamber, and then supplies a drying gas, thereby drying the substrate. In general, a drying chamber is composed of a first chamber body and a second chamber body and is equipped with a damping unit that absorbs shock, such as a spring, to reduce shock between the first chamber body and the second chamber body when the first chamber body and the second chamber body are changed into a sealed state from an open state.

However, environmental particles are produced when such a spring is compressed while the chamber is closed and clamped. Such environmental particles cause critical defects in the semiconductor process.

### SUMMARY OF THE INVENTION

An objective of the present disclosure is to provide an apparatus of processing a substrate that can prevent process defects caused by particles, and a method of processing a substrate.

An objective of the present disclosure is to provide an apparatus of processing a substrate that can effectively remove particles produced from an elastic member coupled to a supercritical drying chamber, and a method of processing a substrate.

The objectives of the present disclosure are not limited thereto and other objectives not stated herein may be clearly understood by those skilled in the art from the following description.

An exemplary embodiment of the present disclosure, an apparatus of processing a substrate, comprising: a housing having an internal space; a process chamber disposed in the internal space and defining a processing space in which a substrate is processed-the process chamber including a first chamber body of which a relative position is fixed with respect to the housing and a second chamber body defining the processing chamber by being combined with the first chamber body; an elevation unit moving the second chamber body with respect to the first chamber body such that the processing space can be switched between a sealed state and an open state; a damping unit coupled to the first chamber body and absorbing shock that is applied to the first chamber body when relative movement is generated between the first chamber body and the second chamber body; and a particle removal unit removing particles produced at the damping unit.

According to an embodiment of the present disclosure, the damping unit is a spring having a hole formed in an up-down direction at a center when seen from above, and the particle removable unit may provide to apply negative pressure to the hole.

According to an embodiment of the present disclosure, the damping unit is a disc spring, and a center hole of the disc spring and the opening may overlap each other when seen from above.

According to an embodiment of the present disclosure, a plurality of damping units is provided, and the particle removable unit may provide at positions corresponding to the damping units, respectively.

According to an embodiment of the present disclosure, the particle removable unit may include, a body member having an opening at a lower end and having a suction space communicating with the opening therein; and a suction mechanism providing negative pressure to the suction space.

According to an embodiment of the present disclosure, the damping unit may fix to a lower end of the body member and the first chamber body.

According to an embodiment of the present disclosure, the apparatus may further include a clamping unit clamping the process chamber when the processing space is in the sealed state; and a moving unit moving the clamping unit between a clamping position where the process chamber is clamped and an unclamping position where the process chamber is unclamped.

According to an embodiment of the present disclosure, a liquid supply unit supplying a processing fluid to the processing space; and a control unit controlling the elevation unit, the particle removal unit, the moving unit, and the fluid supply unit, wherein the control unit controls the elevation unit, the particle removal unit, the moving unit, and the fluid supply unit to perform: an opening step of positioning the first chamber body and the second chamber body at an opening position where the processing space is open; a loading step of loading a substrate into the processing space after the opening step; sealing step of positioning the first chamber body and the second chamber body at a closed position where the processing space is closed after the loading step; a processing step of processing the substrate by supplying a processing fluid to the processing space after the sealing step; and a particle removal step of applying negative pressure to a region where the damping unit is provided by means of the particle removal unit.

According to an embodiment of the present disclosure, the control unit further may controls the particle removal unit and the clamping unit to perform: a clamping step of clamping the first chamber body and the second chamber body by means of the clamping unit between the sealing step and the processing step; and the particle removal step during the clamping step.

According to an embodiment of the present disclosure, the control unit may controls the particle removal unit such that the particle removal unit applies negative pressure to the region, where the damping unit is provided, only in the clamping step among the opening step, the loading step, the sealing step, the clamping step, and the processing step.

According to an embodiment of the present disclosure, the processing fluid may a supercritical fluid.

An exemplary embodiment of the present disclosure, a method of processing a substrate, comprising: an opening step of opening a processing space formed by combining a first chamber body and a second chamber body by moving the second chamber body with respect to the first chamber body; a loading step of loading a substrate into the processing space; a sealing step of sealing the processing space by moving the second chamber body with respect to the first chamber body after the loading step; a processing step of processing the substrate by supplying a processing fluid to the processing space after the sealing step; and a particle removal step of removing particles from a region where a damping unit, which absorbs shock that is applied to the first chamber body when relative movement is generated between the first chamber body and the second chamber body, may provide.

According to an embodiment of the present disclosure, a clamping step of clamping the first chamber body and the second chamber body with the processing space sealed between the sealing step and the processing step, wherein the particle removal step may performed during the clamping step.

According to an embodiment of the present disclosure, the particle removable step may performed only in the clamping step among the opening step, the loading step, the sealing step, or the processing step.

According to an embodiment of the present disclosure, the processing step may a step of drying the substrate using a supercritical fluid.

According to an embodiment of the present disclosure, the damping unit may a spring having a hole formed in an up-down direction at a center when seen from above, and the particle removable step applies negative pressure to the hole.

An exemplary embodiment of the present disclosure, an apparatus of processing a substrate, comprising: a housing having an internal space; a process chamber disposed in the internal space and defining a processing space in which a substrate is processed-the process chamber including a first chamber body of which a relative position is fixed with respect to the housing and a second chamber body defining the processing chamber by being combined with the first chamber body; an elevation unit moving one of the first chamber body and the second chamber body such that the processing space can be switched between a sealed state and an open state; a clamping unit clamping the process chamber when the processing space is in the sealed state; a moving unit moving the clamping unit between a clamping position where the process chamber is clamped and an unclamping position where the process chamber is unclamped; a fluid supply unit supplying a processing fluid to the processing space; a damping unit coupled to the first chamber body and absorbing shock that is applied to the first chamber body when relative movement is generated between the first chamber body and the second chamber body; and a particle removal unit removing particles produced at the damping unit, wherein the apparatus further includes a control unit controlling at least one of the elevation unit, the moving unit, the fluid supply unit, or the particle removal unit, wherein the particle removable unit includes: a body member having an opening at a lower end and having a suction space communicating with the opening therein; and a suction mechanism providing negative pressure to the suction space, wherein the damping unit may a disc spring, and a center hole of the disc spring and the opening overlap each other when seen from above.

According to an embodiment of the present disclosure, a plurality of damping units is provided and the damping unit is a spring having a hole formed in an up-down direction at a center when seen from above, and the particle removable unit may provide at positions corresponding to the damping units, respectively, to apply negative pressure to the hole.

According to an embodiment of the present disclosure, the control unit control the elevation unit, the particle removal unit, the moving unit, and the fluid supply unit to perform: an opening step of positioning the first chamber body and the second chamber body at an opening position where the processing space is open; a loading step of loading a substrate into the processing space after the opening step; sealing step of positioning the first chamber body and the second chamber body at a closed position where the processing space is closed after the loading step; a processing step of processing the substrate by supplying a supercritical fluid to the processing space after the sealing step; and a particle removal step of applying negative pressure to a region where the damping unit may provide by means of the particle removal unit.

According to an embodiment of the present disclosure, a clamping step of clamping the first chamber body and the second chamber body by means of the clamping unit is further performed between the sealing step and the processing step, the particle removal unit and the clamping unit are controlled such that the particle removal step is performed during the clamping step, and the particle removal unit may control to apply negative pressure to the region where the damping unit is provided only in the clamping step among the opening step, the loading step, the sealing step, the clamping step, and the processing step.

According to an embodiment of the present disclosure, it is possible to efficiently process substrates.

According to an embodiment of the present disclosure, it is possible to efficiently perform a drying process by suctioning particles simultaneously with clamping a chamber.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a plan view schematically showing an apparatus of processing a substrate according to an embodiment of the present disclosure.

FIG. 2 is a view schematically showing an embodiment of the liquid processing chamber of FIG. 1.

FIG. 3 is a view schematically showing an embodiment of the drying chamber of FIG. 1.

FIG. 4 is an enlarged view of the portion A of FIG. 3.

FIG. 5 is a flowchart showing a method of processing a substrate according to an embodiment of the present disclosure.

FIG. 6 to FIG. 15 are conceptual views illustrating the method of processing a substrate according to an embodiment of the present disclosure.

FIG. 16 is a view showing a particle removal unit according to another embodiment of the present disclosure.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereafter, an example in which an apparatus of processing a substrate is semiconductor equipment for manufacturing semiconductor devices by processing substrates W is described.

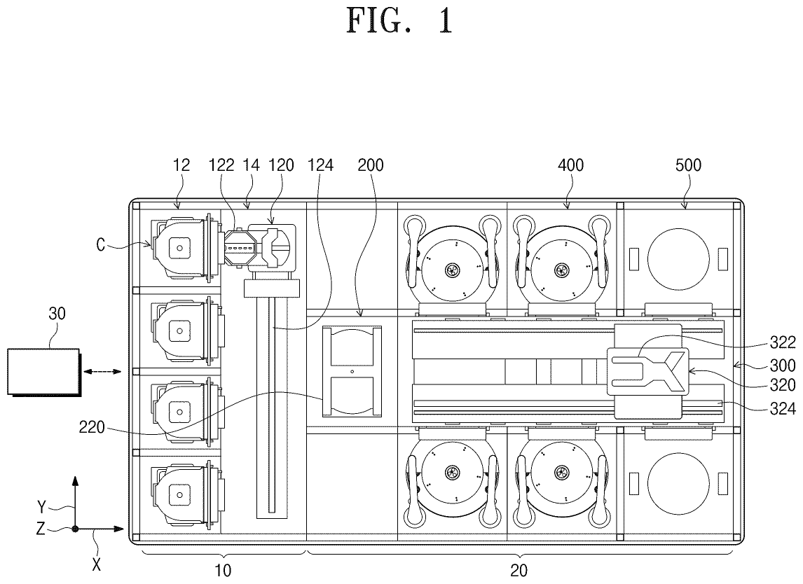

FIG. 1 is a plan view schematically showing an apparatus of processing a substrate according to an embodiment of the present disclosure.

Referring to FIG. 1, an apparatus of processing a substrate includes an index module 10, a processing module 20, and a control unit 30. When seen from above, the index module 10 and the processing module 20 are disposed in one direction. Hereafter, the direction in which the index module 10 and the processing module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates W to the processing module 20 from containers C accommodating the substrates W and loads the substrates W processed at the processing module 20 into the containers C. The longitudinal direction of the index module 10 is provided in the second direction Y. The index module 10 has a load port 12 and an index frame 14. The load port 12 is positioned at the opposite side of the processing module 20 with the index frame 14 therebetween. The container C accommodating substrates W is placed in the load port 12. A plurality of load ports 12 may be provided and the plurality of load ports 12 may be disposed in the second direction Y.

The container C may be a container for sealing such as a Front Open Unified Pod (FOUP). The container C may be placed on the load port 12 by a worker or a conveying device (not shown) such as an overhead transfer, an overhead conveyor, or an automatic guided vehicle.

An index robot 120 is provided on the index frame 14. A guide rail 124 of which the longitudinal direction is provided in the second direction Y is provided on the index frame 14 and the index robot 120 may be provided to be movable on the guide rail 124. The index robot 120 includes a hand 122 on which substrates W are placed and the hand 122 may be provided to be able to move forward and backward, rotate about the third direction Z, and move in the third direction Z. A plurality of hands 122 is provided to be spaced apart from each other in the up-down direction and the hands 122 can move forward and backward independently from each other.

The processing module 20 includes a buffer unit 200, a transfer chamber 300, a liquid processing chamber 400, and a drying chamber 500. The buffer unit 200 provides a space in which substrates W that are loaded into the processing module 20 and substrates W that are unloaded from the processing module 20 temporarily stay. The liquid processing chamber 400 performs a liquid processing process of performing liquid processing on substrates W by supplying a liquid onto the substrates W. The drying chamber 500 can perform a drying process that removes a liquid remaining on substrates W. The transfer chamber 300 transfers substrates W between the buffer unit 200, the liquid processing chamber 400, and the drying chamber 500.

The buffer unit 200 has a plurality of buffers 220 on which substrates W are placed. The buffers 220 may be disposed to be spaced apart from each other in the third direction Z. The buffer 220 may be a substrate holder supporting the bottom surface of a substrate W. The buffer 220 may be provided in the form of a supporting shelf that holds the bottom surface of a substrate W.

The buffer unit 200 is open on the front face and the rear face. The front face is a surface that faces the index module 10 and the rear face is a surface that faces the transfer chamber 300. The index robot 120 can approach the buffer unit 200 through the front face and the transfer robot 320 can approach the buffer unit 200 through the rear face.

The longitudinal direction of the transfer chamber 300 may be provided in the first direction X. The buffer unit 200 may be disposed between the index module 10 and the transfer chamber 300. The liquid processing chamber 400 and the drying chamber 500 may be disposed on sides of the transfer chamber 300. The liquid processing chamber 400 and the transfer chamber 300 may be disposed in the second direction Y. The drying chamber 500 and the transfer chamber 300 may be disposed in the second direction Y. The buffer unit 200 may be positioned at an end of the transfer chamber 300.

According to an embodiment, the liquid processing chambers 400 may be disposed at both sides of the transfer chamber 300, the drying chambers 500 may be disposed at both sides of the transfer chamber 300, and the liquid processing chambers 400 may be disposed at positions close to the buffer unit 200 in comparison to the drying chambers 500. The liquid processing chambers 400 may be provided in an array of A×B (A and B are each a natural number of 1 or more) in the first direction X and the third direction Z, respectively, at a side of the transfer chamber 300. Further, the drying chambers 500 may be provided by the number of C×D (C and D are each a natural number of 1 or more) in the first direction X and the third direction Z, respectively, at a side of the transfer chamber 300. Unlike the above description, only the liquid processing chambers 400 may be provided at a side of the transfer chamber 300 and only the drying chambers 500 may be provided at another side.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates W are placed and the hand 322 may be provided to be able to move forward and backward, rotate about the third direction Z, and move in the third direction Z. A plurality of hands 322 is provided to be spaced apart from each other in the up-down direction and the hands 322 can move forward and backward independently from each other.

The control unit 30 can control the apparatus of processing a substrate. The control unit 30 may include: a process controller that is a microprocessor (computer) that performs control of the apparatus of processing a substrate; a user interface that is a keyboard through which an operator performs command input operation, etc. to manage the apparatus of processing a substrate, a display that visualizes and displays the operation situation of the apparatus of processing a substrate, etc.; and a memory that stores a control program for performing processing, which is performed in the apparatus of processing a substrate, under control of the process controller, a program for performing processing on each component in accordance with various data and processing conditions, that is, a processing recipe. Further, the user interface and the memory may be connected to the process controller. The processing recipe may be stored in a memory medium of the memory and the memory medium may be a hard disk and may be a portable disc, such as a CD-ROM and a DVD, or a semiconductor memory such as a flash memory.

The control unit 30 can control the components of the apparatus of processing a substrate to be able to perform the method of processing a substrate to be described below.

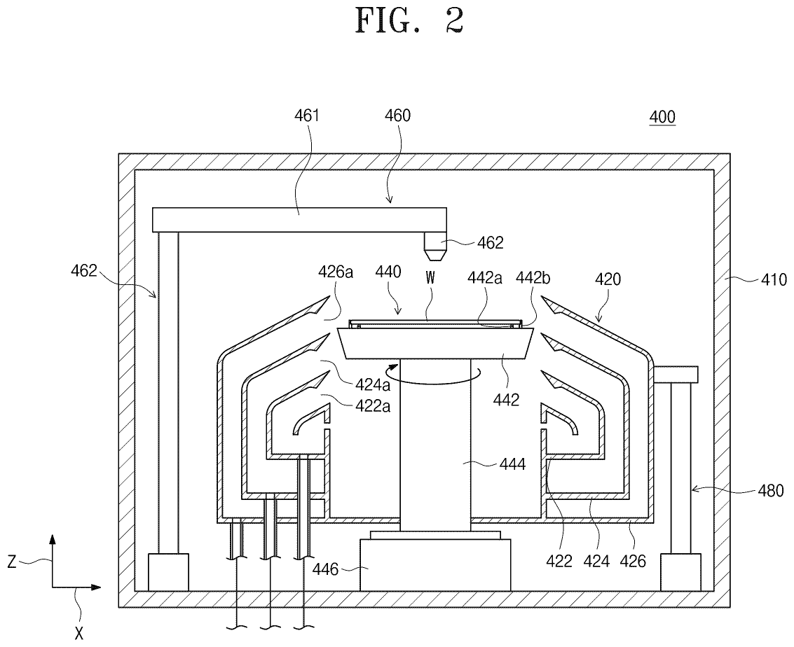

FIG. 2 is a view schematically showing an embodiment of the liquid processing chamber of FIG. 1.

Referring to FIG. 2, the liquid processing chamber 400 includes a housing 410, a processing container 420, a supporting unit 440, a liquid supply unit 460, and an elevation unit 480.

The housing 410 may have an internal space in which substrates W are processed. The housing 410 may have a substantially hexahedral shape. For example, the housing 410 may have a rectangular cuboid shape. Further, an opening (not shown) through which substrates W are loaded or unloaded may be formed on the housing 410. Further, a door (not shown) selectively opening and closing the opening may be installed on the housing 410.

The processing container 420 may have a box shape with an open top. The processing container 420 can provide a processing chamber in which substrates W are processed, and the supporting unit 440 supports a substrate W in the processing space. The liquid supply unit 460 supplies a processing solution to a substrate W supported on the supporting unit 440. A plurality of kinds of processing solutions is provided and may be sequentially supplied to a substrate W. The elevation unit 480 adjusts the relative height between the processing container 420 and a substrate W on the supporting unit 440.

According to an embodiment, the processing container 420 has a plurality of recovery tanks 422, 424, and 426. The recovery tanks 422, 424, and 426 each have a recovery space for recovering liquid used to process substrates. The recovery tanks 422, 424, and 426 are each provided in a shape surrounding the supporting unit 440. The processing solutions splashed by rotation of a substrate W when the liquid processing process is performed flow into the recovery spaces through inlets 422a, 424a, and 426a of the recovery tanks 422, 424, and 426, respectively. According to an embodiment, the processing container 420 has a first recovery tank 422, a second recovery tank 424, and a third recovery tank 426. The first recovery tank 422 is disposed to surround the supporting unit 440, the second recovery tank 424 is disposed to surround the first recovery bath 422, and the third recovery tank 426 is disposed to surround the second recovery tank 424.

The second inlet 424a for supplying liquid into the second recovery tank 424 may be positioned higher than the first inlet 422a for supplying liquid into the first recovery tank 422, and the third inlet 426a for supplying liquid into the third recovery tank 426 may be positioned higher than the second inlet 424a.

The supporting unit 440 has a supporting plate 442 and an actuating shaft 444. The top surface of the supporting plate 442 is provided substantially in a circular shape and may have a diameter larger than substrates W. Supporting pins 442a supporting the backside of a substrate W may be provided in the edge region of the top surface of the supporting plate 442. The upper ends of the supporting plates 442a protrude from the supporting plate 442 so that a substrate W is spaced a predetermined distance apart from the supporting plate 442.

Further, chuck pins 442b are provided in the edge region of the top surface of the supporting plate 442. The chuck pins 442b may be provided outside the supporting pins 442a. The chuck pins 442b protrude upward from the supporting plate 442 and chuck the side of a substrate W to prevent the substrate W from separating from the supporting unit 440 when the substrate W is rotated. The actuating shaft 444 is driven by an actuator 446, is connected with the center of the underside of the supporting plate 442, and rotates the supporting plate 442 about the center axis thereof.

The liquid supply unit 460 can supply a processing solution to substrates W. The liquid supply unit 460 may include an arm 461, a nozzle 462, and an actuator 463. The nozzle 462 may be installed at an end of the arm 461 having a bar shape. The actuator 463 is configured in the form of a rotary shaft having the third direction Z as a rotation axis and may be connected with another end of the arm 461. The actuator 463 can rotate the arm 461 by rotating around the third direction Z as the rotation axis. Accordingly, the position of the nozzle 462 installed at an end of the arm 461 can be changed.

The nozzle 462 can supply a processing solution to a substrate W. The processing solution may be a chemical, a rinsing solution, or an organic solvent. The chemical may be a chemical that has the property of strong acid or strong base. Further, the rinsing solution may be deionized water. Further, the organic solvent may be isopropyl alcohol (IPA).

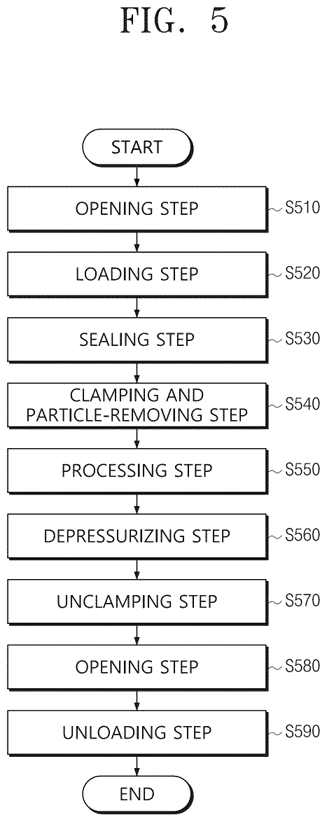

Only one nozzle 462 is shown in FIG. 5, but the liquid supply unit 460 may include a plurality of nozzles 462 and the nozzles 462 may be configured to supply different kinds of processing solutions. For example, any one of the nozzles 462 may supply a chemical, another one of the nozzles 462 may supply a rinsing solution, and another one of the nozzles 462 may supply an organic solvent. Further, the control unit 30 can control the liquid supply unit 460 to supply a rinsing solution to a substrate W from another one of the nozzles 462 and then supply an organic solvent from another one of the nozzles 462. Accordingly, the rinsing solution supplied on the substrate W can be replaced with the organic solvent with low surface tension.

The elevation unit 480 can straightly move the processing container 420 in the up-down direction. The relative height between the processing container 420 and a substrate W is changed by up-down movement of the processing container 420. The elevation unit 480 may be equipped with a power generation device such as a motor, a pneumatic cylinder, or a hydraulic cylinder. The elevation unit 480 can switch the recovery tanks 422, 424, and 426 for recovering processing solutions in accordance with the kinds of liquid that is supplied to substrates W by adjusting the height of the processing container 420.

Unlike the above description, the processing container 420 may be fixedly installed and the supporting plate 442 may be configured to be able to move in the up-down direction.

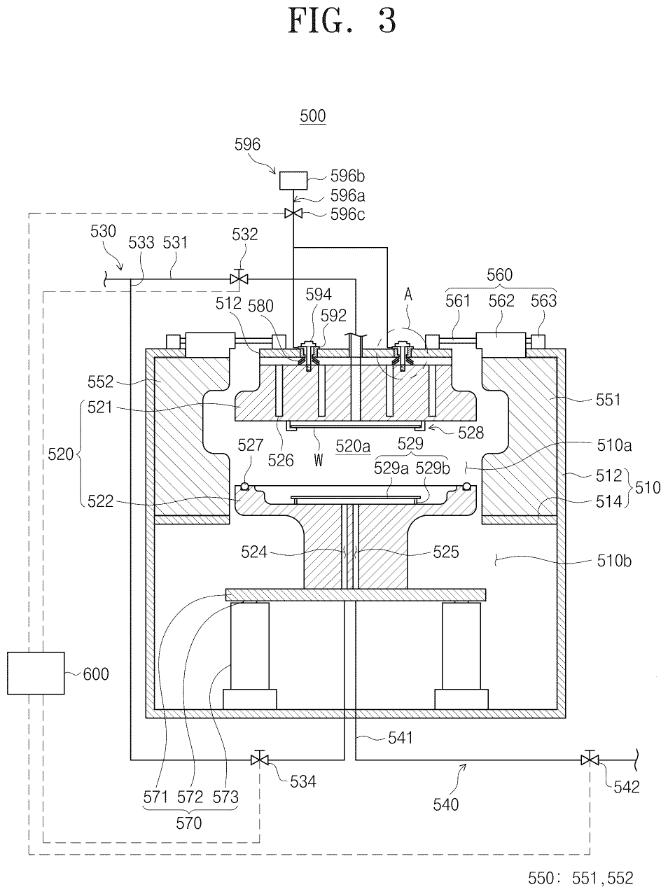

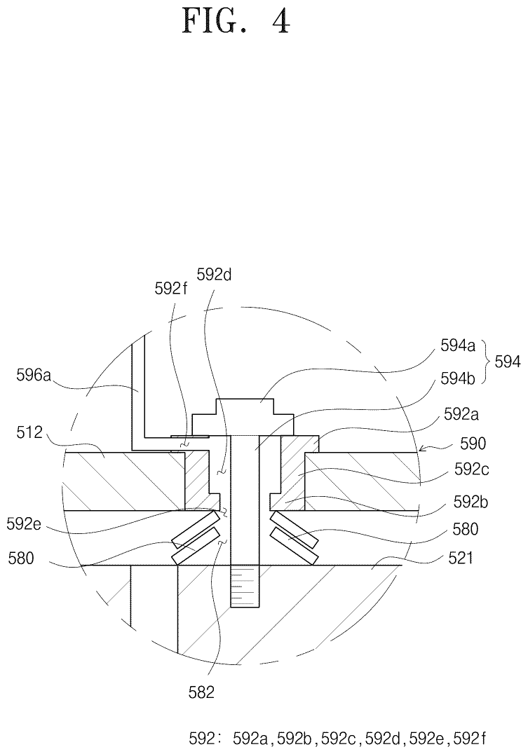

FIG. 3 is a view schematically showing an embodiment of the drying chamber of FIG. 1. FIG. 4 is an enlarged view of the portion A of FIG. 3.

Referring to FIG. 3, the drying chamber 500 according to an embodiment of the present disclosure may include a base frame 510, a chamber 520, a fluid supply unit 530, a fluid exhaust unit 540, a clamping unit 550, a moving unit 560, an elevation unit 570, a damping unit 580, a particle removal unit 590, and a control unit 600.

The base frame 510 can provide an internal space in which the chamber 520 to be described below can be disposed. The base frame 510 may include a housing 512 and an intermediate plate 514.

The housing 512 may have a container shape having an overall rectangular cuboid shape. The housing 512 may have an internal space. The chamber 520, first and second clamping bodies 551 and 552 of the clamping unit 550, the elevation unit 570, the damping unit 580, etc. can be disposed in the internal space of the housing 512.

The intermediate plate 514 is installed in the internal space of the housing 512 and may have a plate shape with a hole formed at the center region. The internal space of the housing 512 may be divided into an upper space 510a and a lower space 510b by the intermediate plate 514. The first chamber body 521 and the first and second clamping bodies 551 and 552 may be disposed in the upper space 510a and the elevation unit 570 may be disposed in the lower space 510b. The second chamber body 521 to be described below can be moved between the lower space 510b and the upper space 510a by the elevation unit 570. The second chamber body 522 can move between the upper space 510a and the lower space 510b through the hole formed at the intermediate plate 514.

Further, a plurality of moving units 560 to be described below may be formed on the housing 512. Some of the moving units 560 may be configured to move the first clamping body 521 and some of the other moving units 560 may be configured to move the second clamping body 522.

The chamber 520 may include the first chamber body 521 and the second chamber body 522. The second chamber body 522 may be positioned under the first chamber body 521. The first chamber body 521 may be an upper body positioned at the upper portion and the second chamber body 522 may be a lower body positioned at the lower portion.

The first chamber body 521 may have a shape that has a flat bottom surface and in which the height of the center region of the top surface is larger than the height of the edge region of the top surface. The second chamber body 522 may have a shape in which the top surface is recessed downward to be able to define processing space 520a and the height of the edge region of the bottom surface is larger than the height of the center region of the bottom surface. When the first chamber body 521 and the second chamber body 522 are combined with each other, at least a portion of the edge regions of the first chamber body 521 and the second chamber body 522 can be inserted into the clamping bodies 551 and 552 to be described below.

The chamber 520 can provide a processing space 520a in which substrates W are processed. The first chamber body 521 and the second chamber body 522 can provide the processing space 520a in which substrates W are processed by being combined with each other. The processing space 520a can be opened or sealed by movement of any one of the first chamber body 521 or the second chamber body 522.

For example, the second chamber body 522 can define a sealed processing space 520a together with the first chamber body 521, selectively, together with the first chamber body 521 and a sealing member 527 by moving upward. The position of the second chamber body 522 in this state can be defined as a closed position. Further, the second chamber body 522 can open the processing space 520a by moving away from the first chamber body 521 by moving downward. The position of the second chamber body 522 in this state can be defined as an open position.

A first supply port 523 may be provided in the first chamber body 521. The first supply port 523 may be provided by forming a hole in the first chamber body 521 itself or by inserting a pipe in a hole formed in the first chamber body 521.

A first fluid supply line 531 to be described below may be connected to the first supply port 523. The first supply port 523 can supply a processing fluid to the processing space 520a. An outlet of the first supply port 523 may be configured to face the lower region of the processing space 520a. The outlet of the first supply port 523 may face the top surface of a substrate W on a supporting member 528.

A second supply port 522 and an exhaust port 525 may be provided in the second chamber body 521. The second supply port 522 and the exhaust port 525 may be provided by forming a hole in the second chamber body 522 itself or by inserting a pipe in holes formed in the second chamber body 522.

A second fluid supply line 533 to be described below may be connected to the second supply port 524. The second supply port 523 can supply a processing fluid to the processing space 520a. An outlet of the second supply port 524 may be configured to face the upper region of the processing space 520a. The outlet of the second supply port 524 may be disposed to fact a shielding member 529 to be described below.

An exhaust line 541 to be described below may be connected to the exhaust port 525. The exhaust port 525 may be positioned in parallel with the second supply port 524. The exhaust port 525 can exhaust the atmosphere of the processing space 520a through the exhaust line 541.

A heater 526, a sealing member 527, a supporting member 528, and shielding member 529 may be provided in the chamber 520.

The heater 526 may be embedded in the chamber 520. The heater 526 can maintain the temperature of the processing space 520a at a set temperature by generating heat. The set temperature may be a temperature above a critical temperature at which the processing fluid supplied to the processing space 520a can be maintained in a supercritical state. The heater 526 may be embedded in the first chamber body 521. However, the present disclosure is not limited thereto and the heater 526 may be embedded in the second chamber body 522.

The sealing member 527 can seal the processing space 520a to prevent the processing fluid supplied to the processing space 520a from leaking from the processing space 520a when the second chamber body 522 is at the closed position. The sealing member 527 may be an O-ring. The sealing member 527 may be made of a material having elasticity. The sealing member 527 may be made of rubber or a plastic material having elasticity.

The sealing member 527 may be installed between the first chamber body 521 and the second chamber body 522. For example, the sealing member 527 may be inserted in a ring-shaped groove formed in the edge region of the top surface of the second chamber body 522.

The supporting member 528 can support a substrate W. The supporting member 528 may be configured to support the bottom surface of a substrate W. The supporting member 528 may be installed on the bottom surface of the first chamber body 521. The supporting member 528 may be provided in a pair. The supporting member 528 may have a shape extending downward and horizontally bending at the end portion. The supporting member 528 may be configured to support only the edge region of the bottom surface of a substrate W, thereby being able to reduce the risk of scratches that may occur on the bottom surface of substrate W.

The shielding member 529 can prevent a high-pressure processing fluid, which is supplied from the second supply port 524, from being directly supplied to the bottom surface of a substrate W. The shielding member 529 may include a shielding plate 529a facing the outlet of the second supply port 524 and a leg 529b spacing the shielding plate 529a from the second chamber body 522.

The fluid supply unit 530 can supply a processing fluid to the processing space 520a. The fluid supply unit 530 can supply carbon dioxide, which is a supercritical fluid, to the processing space 520a. The processing fluid that is supplied to the processing space 520a can dry a substrate W by removing an organic solvent that may remain on the substrate W such as IPA.

The fluid supply unit 530 may include a first supply line 531, a first supply valve 532, a second supply line 533, and a second supply valve 534. The first supply line 531 and the second supply line 533 can receive a processing fluid from a liquid supply source (not shown) and supply the processing fluid to the processing space 520a. The first supply line 531 is connected with the first supply port 523 described above and can supply a processing fluid to the upper portion of the processing space 520a. The second supply line 533 is connected with the second supply port 524 described above and can supply a processing fluid to the lower portion of the processing space 520a.

The first supply valve 532 and the second supply valve 534 are installed on the first supply line 531 and the second supply line 533, respectively, and can allow or block flow of a processing fluid through the first supply line 531 and the second supply line 533. The first supply valve 532 and the second supply valve 534 are automatic valves.

The fluid exhaust unit 540 can exhaust the atmosphere of the processing space 520a. The fluid exhaust unit 540 can exhaust the processing fluid supplied to the processing space 520a out of the drying chamber 500. The fluid exhaust unit 540 may include an exhaust line 541, an exhaust valve 542, and a pressure reducer 543.

The exhaust line 541 is connected with the exhaust port 525 described above and exhausts the atmosphere of the processing space 520a through the exhaust port 525, thereby being able to depressurize the processing space 520a. The exhaust line 541 is connected with the pressure reducer 543 such as a pump and the pressure reducer 543 can provide depressurization for exhausting the processing space 520a.

The exhaust valve 542 is installed on the exhaust line 541 and can allow or block flow of a processing fluid through the exhaust line 541. The exhaust valve 542 may be an automatic valve.

The clamping unit 550 can clamp the chamber 520. The clamping unit 550 can clamp the chamber 520 when the second chamber body 522 is at the closed position. The clamping unit 550 can prevent an excessive load, which is applied to the elevation unit 570 to seal the processing space 520a, by clamping the chamber 520 while a substrate is processed.

The clamping unit 550 may include a first clamping body 551 and a second clamping body 552. The first clamping body 551 and the second clamping body 552 may have shapes symmetric to each other. The first clamping body 551 and the second clamping body 552 may have a groove recessed away from the chamber 520 in the center region facing the chamber 520. The edge region of the chamber 520 can be inserted in the groove.

The moving unit 560 can move the clamping bodies 551 and 552 between a clamping position and an unclamping position. The clamping position may be a position at which the chamber 520 is clamped when the second chamber body 522 is at the closed position. In this case, the clamping position may mean that the edge portion of the chamber 520 is inserted in the grooves formed on the clamping bodies 551 and 552. The unclamping position may mean a position at which the edge portion of the chamber 520 is separated from the grooves formed on the clamping bodies 551 and 552.

A plurality of moving units 560 may be provided. The moving units 560 may be installed on the top of housing 512. The moving units 560 are installed on the top of the housing 512 and can horizontally move the first clamping body 551 and the second clamping body 552. The moving units 560 each may include a guide rail 561, a bracket 562, and an actuator 563. The actuator 563 may be a motor, an air cylinder, or a hydraulic cylinder. Alternatively, the moving unit 560 may be configured such that a bracket 562 moves along the guide rail 561 in a magnetic levitation type. The guide rail 561 may horizontally extend. The bracket 562 is configured to be able to move along the guide rail 561 and the lower portion may be coupled to the upper portions of the first and second clamping bodies 551 and 552.

It is exemplified with reference to FIG. 3 in the above description that the moving unit 560 is positioned over the first and second clamping bodies 551 and 552, but the present disclosure is not limited thereto. For example, the moving unit 560 may be installed under the intermediate plate 514. That is, the moving unit 560 may be positioned under the first and second clamping bodies 551 and 552 to horizontally move the first and second clamping bodies 551 and 552.

The elevation unit 570 can move the second chamber body 522 that may be a lower chamber body. The elevation unit 570 can change the processing space 520a into the sealed state or the open state by moving the second chamber body 522 in the up-down direction. The elevation unit 570 may include a moving plate 571, a lower moving shaft 572, and a lower actuator 573. The lower portion of the second chamber body 522 may be fastened to the upper portion of the moving plate 571. The lower moving shafts 572 may be fastened to the lower portion of the moving plate 571. The lower moving shaft 572 can be moved in the up-down direction by the lower actuator 573. The lower actuator 573 may be any one selected from an air cylinder, a hydraulic cylinder, and a motor. Alternatively, the elevation unit 570 may be configured such that the lower moving shaft 572 is moved in the up-down direction in a magnetic levitation type.

The damping unit 580 may be disposed between the housing 512 and the first chamber body 521. The damping unit 580 may be disposed between the housing 512 and the first chamber body 521. Tow damping units 580 are shown in the figures, but this is an example and the present disclosure is not limited thereto.

The damping unit 580 may be coupled to the first chamber body 521. The damping unit 580 can reduce shock that is applied to the first chamber body 521 when relative movement is generated between the first chamber body 521 and the second chamber body 522. In this case, particles may be produced at the damping unit 580.

The damping unit 580 may be a spring having a shape having a hole formed in the up-down direction at the center when seen from above. The area of the upper end of the hole may be smaller than the area of the lower end. In an embodiment, the damping unit 580 may be a disc spring.

Referring to FIG. 3 to FIG. 4, the particle removal unit 590 may be provided at a position adjacent to the damping unit 580. Only two particle removal units 590 are shown in the figures, but this is an example and the particle removal unit 590 may be provided in a quantity corresponding to the number of the damping unit 580. The particle removal unit 590 can remove particles produced at the damping unit 580. Particles may be produced due to relative movement between the first chamber body 521 and the second chamber body 522.

The particle removal unit 590 may include a body member 592, a fixing member 594, and a suction mechanism 596.

The body member 592 may include a first body portion 592a, a second body portion 592b, a third body portion 592c, a suction space 592d, and an opening 592e.

The first body portion 592a may be formed at the upper portion of the body member 592. A portion of the top surface of the first body portion 592a can be supported by the housing 512. The first body portion 592a may include a hole 592f. The hole 592f may be formed horizontally through the first body portion 592a. It is shown in the figures that the hole 952f is formed only on one side of the first body portion 592a, but this is an example and the hole 592f may be formed only on both sides of the first body portion 592a.

The second body portion 592a may be formed at the lower portion of the body member 592. The outer surface of the second body portion 592b may be in contact with the housing and the bottom surface thereof may be in contact with the damping unit 580. The cross-sectional area of the second body portion 592b may be larger than the cross-sectional area of the first body portion 592a.

The third body portion 592c may be connected with the first body portion 592a and the second body portion 592b. The outer surface of the third body portion 592c may be in contact with the housing 512. The cross-sectional area of the third body portion 592c may be smaller than the cross-sectional area of the second body portion 592d.

The suction space 592d may be a space formed inside the body member 592. The suction space 592d may be the space surrounded by the first body portion 592a to the third body portion 592c. The suction space 592d may communicate with the hole 592f of the first body portion 592a.

The opening 592e may be a space formed at the lower end of the second body portion 592b. The opening 592e may communicate with the hole 582 of the damping unit 580 and the suction space 592d.

The fixing member 594 can fix the particle removal unit 590. In an embodiment, the fixing member 594 may be a bolt.

The fixing member 594 may include a first fixing portion 594a and a second fixing portion 594b. The first fixing portion 594a may be supported by the body member 592. The first fixing portion 594a can close the top of the particle suction unit 590. The cross-sectional area of the upper portion of the first fixing portion 594a may be smaller than the cross-sectional area of the lower portion.

The second fixing portion 594b may be connected with the first fixing portion 594a. The second fixing portion 594b can be inserted in the suction space 592d and the hole 582 of the damping unit 580. The lower portion of the second fixing portion 594b may pass through the first chamber body 521.

In an embodiment, the second fixing portion 594b may be omitted.

In an embodiment, the second fixing portion 594b may be in contact with the first chamber body 521.

In an embodiment, the second fixing portion 594b may be spaced apart from the first chamber body 521. In this case, the second fixing portion 594b may not be inserted in the hole 582 of the damping unit 580.

The suction mechanism 596 can suctions particles produced at the damping unit 580. The suction mechanism 596 may include a suction line 596a, a suction device 596b, and a suction valve 596c. The suction line 596a can connect the body member 592 and the suction device 596b.

The suction device 596b can remove particles produced by the damping unit 580 through the suction line 596a. The suction device 596b can suction particles produced by the damping unit 580 by providing negative pressure to the suction space 592b through the suction line 596a. The particles can be suctioned to the suction device 596b through the hole 582 of the damping unit 580, and the opening 592e, the suction space 592b, and the hole 592f of the body member 592, and the suction line 596a.

The suction valve 596c is installed on the suction line 596a and can allow or block flow of particles in the suction line 596a. The suction valve 596c may be an automatic valve.

The control unit 600 may be electrically connected with the fluid supply unit 530, the fluid exhaust unit 540, and the particle suction unit 590. The control unit 600 may be the same as the control unit 30 shown in FIG. 1. The control unit 600 can control the fluid supply unit 530, the fluid exhaust unit 540, and the particle suction unit 590. The control unit 600 can control the first supply valve 532, the second supply valve 534, the exhaust valve 542, and the suction valve 596c. The control unit 600 can control the fluid supply unit 530, the fluid exhaust unit 540, and the particle suction unit 590 by turning on/off the first supply valve 532, the second supply valve 534, the exhaust valve 542, and the suction valve 596c that are automatic valves.

Further, though not shown in the figures, the control unit 600 may be electrically connected with the moving unit 560 and the elevation unit 570 and can control the moving unit 560 and the elevation unit 570. The control unit 600 can control the moving unit 560 by instructing the moving unit 560 to move the clamping bodies 551 and 552 between the clamping position and the unclamping position. Further, the control unit 600 can control the elevation unit 570 by giving an instruction to change the processing space 520a into the sealed state or the open state.

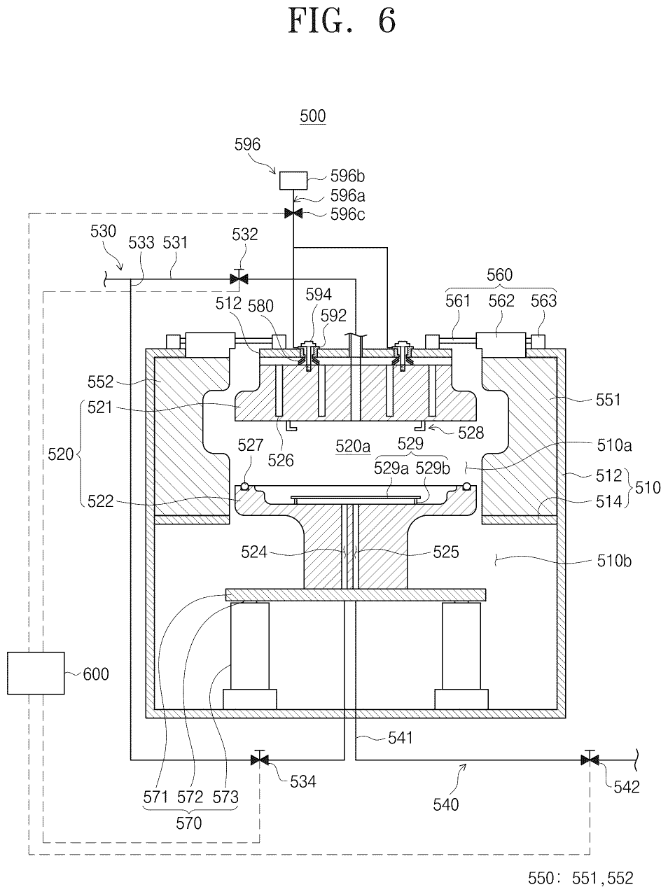

FIG. 5 is a flowchart showing a method of processing a substrate according to an embodiment of the present disclosure. FIG. 6 to FIG. 15 are views illustrating the method of processing a substrate according to an embodiment of the present disclosure.

Referring to FIG. 5, the apparatus of processing a substrate can perform an opening step (S510). Referring to FIG. 6, the control unit 600 can instruct the elevation unit 570 to change the processing space 520a in the sealed state into the opening state. The elevation unit 570 can change the processing space 520a in the sealed state into the open state by moving down the second chamber body 522 in accordance with the instruction of the control unit 600.

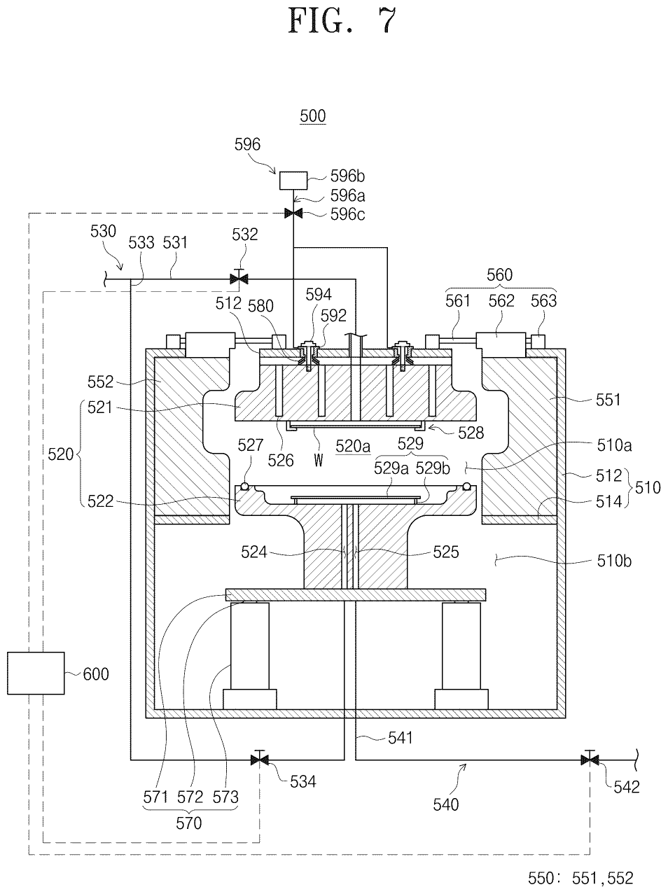

The apparatus of processing a substrate can perform a loading step (S520). Referring to FIG. 7, the control unit 30 can instruct the transfer chamber 300 to load a substrate W into the processing space 520a. The substrate W may have undergone a liquid processing process in the liquid processing chamber 400. The transfer chamber 300 can load the substrate W into the processing chamber 520a in accordance with the instruction of the control unit 30.

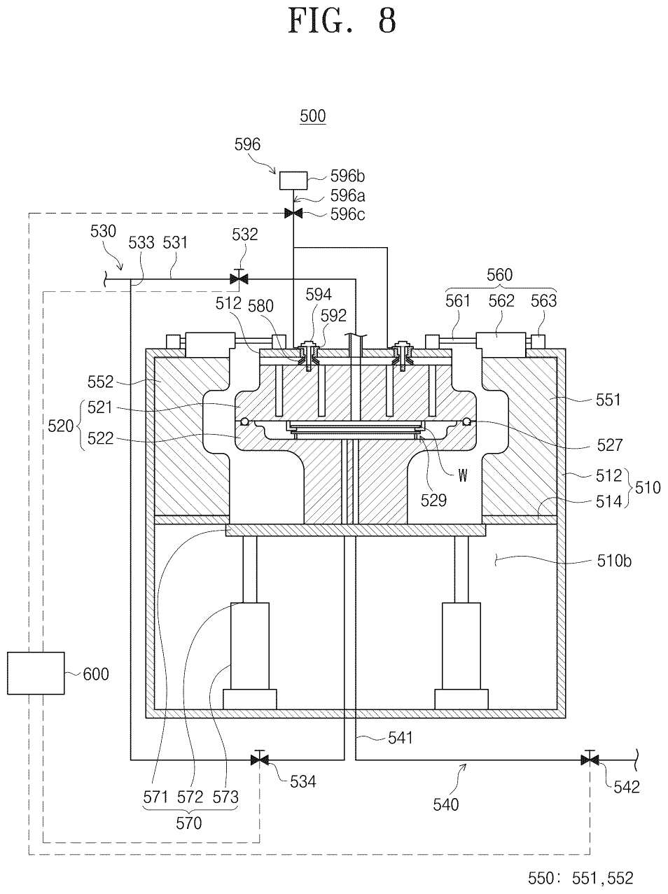

The apparatus of processing a substrate can perform a sealing step (S530). Referring to FIG. 8, the control unit 600 can instruct the elevation unit 570 to change the processing space 520a in the opening state into the sealed state. The elevation unit 570 can change the processing space 520a in the open state into the sealed by moving up the second chamber body 522 in accordance with the instruction of the control unit 600.

The elevation unit 570 can move the second chamber body 522 up to a position where the second chamber body 522 comes in contact with the first chamber body 521 and the sealing member 527 can be compressed. When the sealing step is finished, the upward force applied by the elevation unit 570 is not transmitted to the first body chamber 521, and only an upward force applied while the sealing member 527 is compressed can be transmitted to the first chamber body 521. In this case, the height of the first chamber body 521 is not changed. To this end, the damping unit 580 may be a spring having a modulus of elasticity at which it is not compressed by the upward force applied to the first chamber body 521 by compression of the sealing member 527.

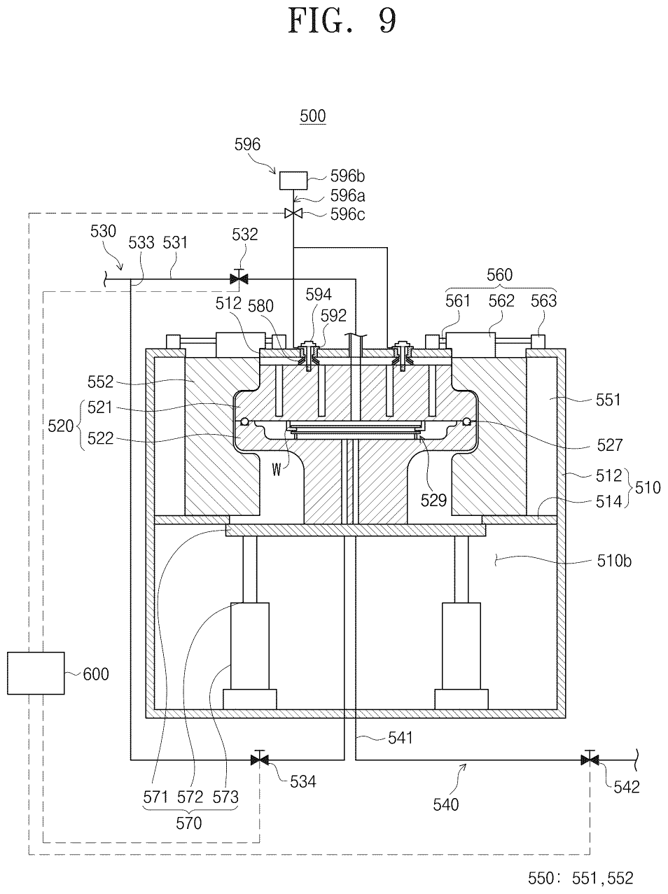

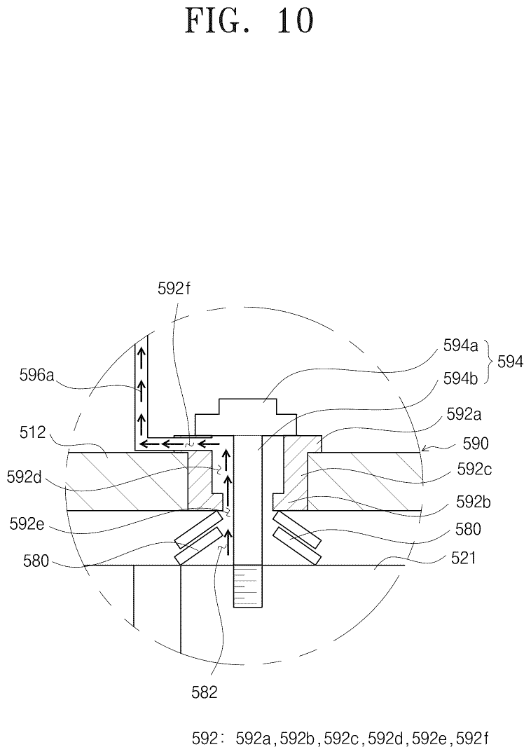

The apparatus of processing a substrate can perform a clamping and particle-removing step (S540). Referring to FIG. 9 and FIG. 10, the control unit 600 can instruct the moving unit 560 to clamp the chambers 520 by moving the clamping unit 550. The moving unit 560 can clamp the chamber 520 by moving the clamping bodies 551 and 552 toward the chamber 520.

The control unit 600 can instruct the elevation unit 570 to bring the chamber 520 into close contact with the clamping unit 550. The elevation unit 570 can bring the chamber 520 into close contact with the clamping bodies 551 and 552 by further moving the second chamber body 522 at the closed position. In more detail, the elevation unit 570 can bring the first chamber body 521 into close contact with the upper portion of the hole formed in the clamping bodies 551 and 552 by further moving up the second chamber body 522. In this case, the damping unit 580 can be compressed by the upward force applied by the elevation unit 570, whereby particles may be produced at the damping unit 580. The particles may be produced in the hole 582 of the damping unit 580.

Simultaneously, the control unit 600 can instruct the particle removal unit 590 to remove the particles. The particle removal unit 590 can provide negative pressure to the suction space 592d through the suction device 596b and can suction the particles produced by the damping unit 580. The particles can be suctioned to the suction device 596b through the hole 582 of the damping unit 580, and the opening 592e, the suction space 592b, and the hole 592f of the body member 592, and the suction line 596a.

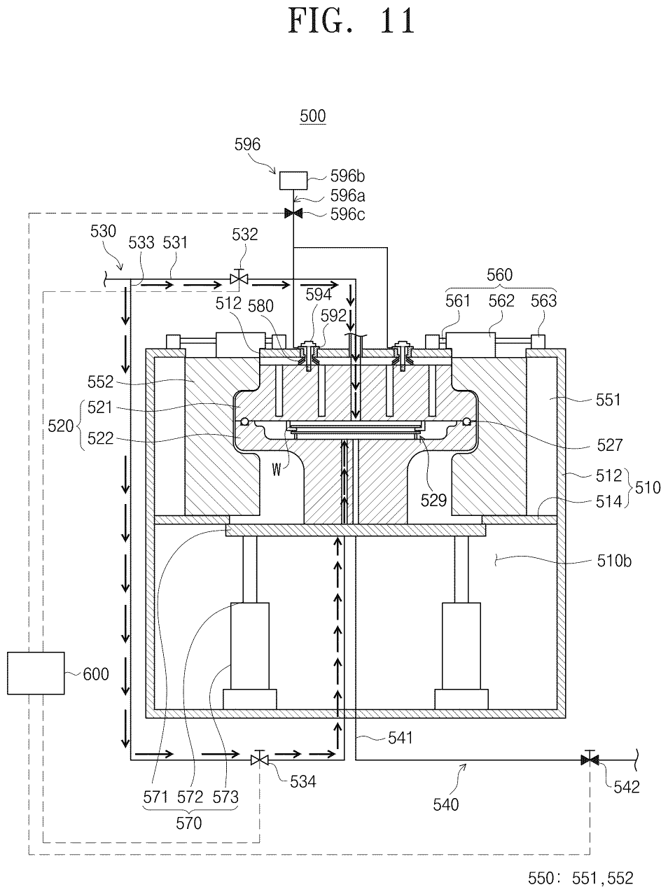

The apparatus of processing a substrate can perform a processing step (S550). The processing step S550 may be a step of drying the substrate loaded in step S520 using a supercritical fluid. Referring to FIG. 11, the control unit 600 can instruct the fluid supply unit 530 to supply a processing fluid into the chamber 520. The processing fluid may be carbon dioxide in a supercritical state. The fluid supply unit 530 can supply a processing fluid to the upper portion of the chamber 520 through the first fluid supply line 531 and/or can supply a processing fluid to the lower portion of the chamber 520 through the second fluid supply line 533. In this case, the inside of the chamber 520 may be at high pressure. In step S520, a drying process can be performed on the substrate W loaded in the chamber 520.

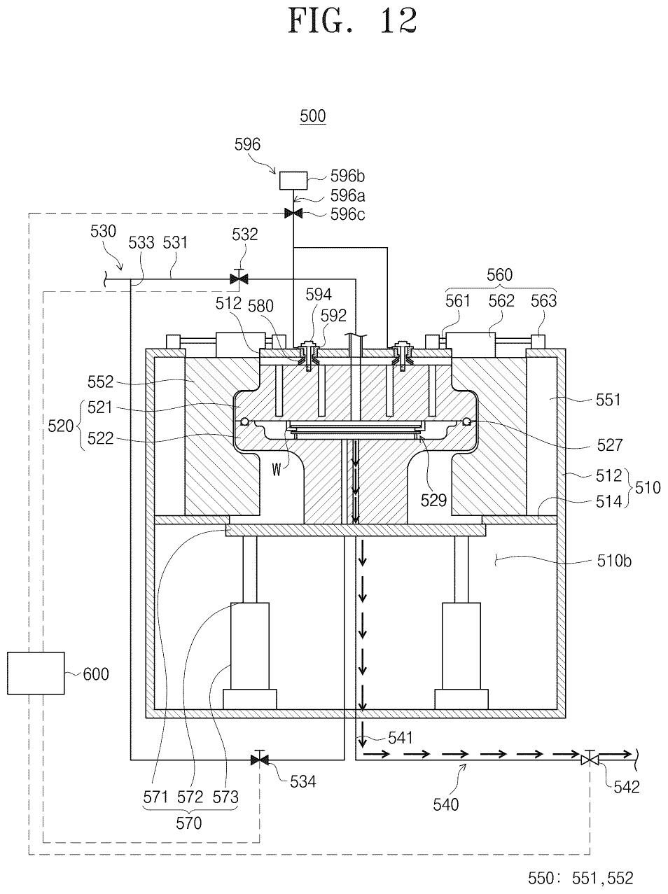

The apparatus of processing a substrate can perform a depressurization step (S560). Referring to FIG. 12, the control unit 600 can instruct the fluid exhaust unit 540 to exhaust the processing fluid in the chamber 520. The fluid exhaust unit 540 can exhaust the processing fluid in the chamber 520 to the outside through the exhaust line 541.

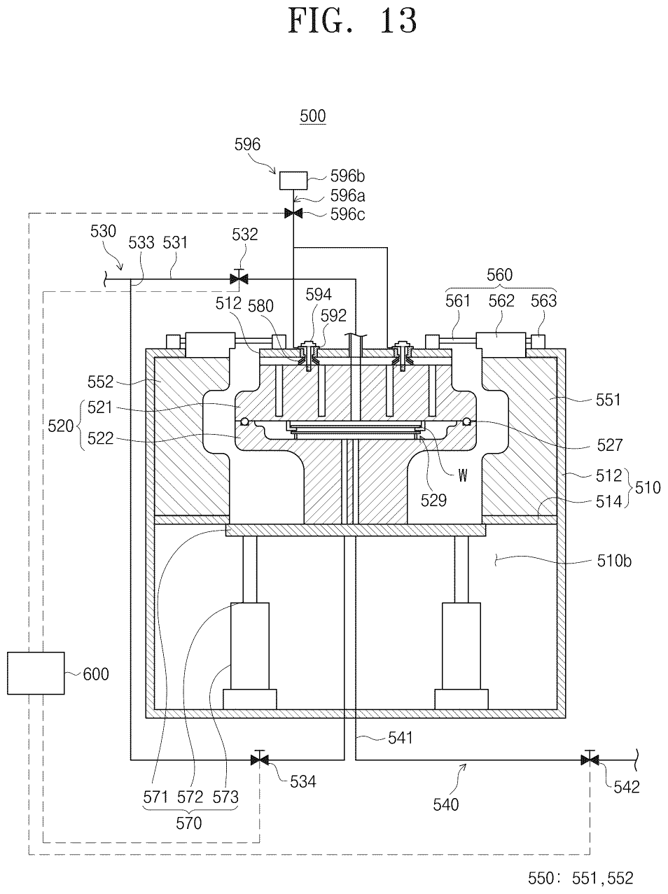

The apparatus of processing a substrate can perform an unclamping step (S570). Referring to FIG. 13, the control unit 600 can instruct the elevation unit 570 to move the chamber 520 away from the clamping unit 550. The elevation unit 570 can move the chamber 520 away from the clamping unit 550 by moving the chamber 520 brought in contact with the clamping unit 550 in step S540. The elevation unit 570 can move the second chamber body 522 to move the chamber 520 to the closed position.

The control unit 600 can instruct the moving unit 560 to unclamp the chambers 520 by moving the clamping unit 550. The moving unit 560 can unclamp the chamber 520 by moving the clamping bodies 551 and 552 away from the chamber 520. In this case, the processing space 520a may be in the sealed state.

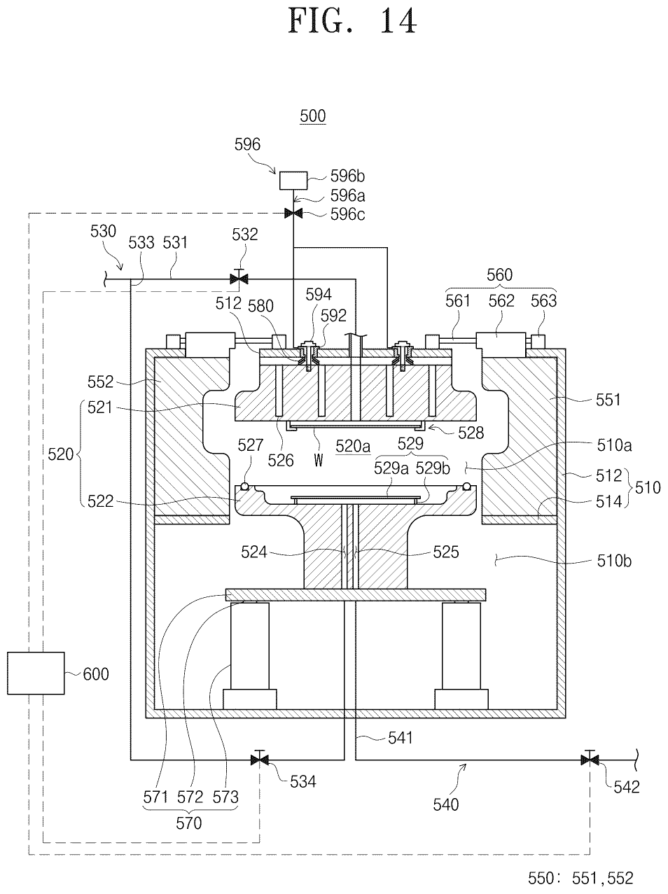

The apparatus of processing a substrate can perform an opening step (S580). Referring to FIG. 14, the control unit 600 can instruct the elevation unit 570 to change the processing space 520a in the sealed state into the opening state. The elevation unit 570 can change the processing space 520a in the sealed state into the open state by moving down the second chamber body 522 in accordance with the instruction of the control unit 600.

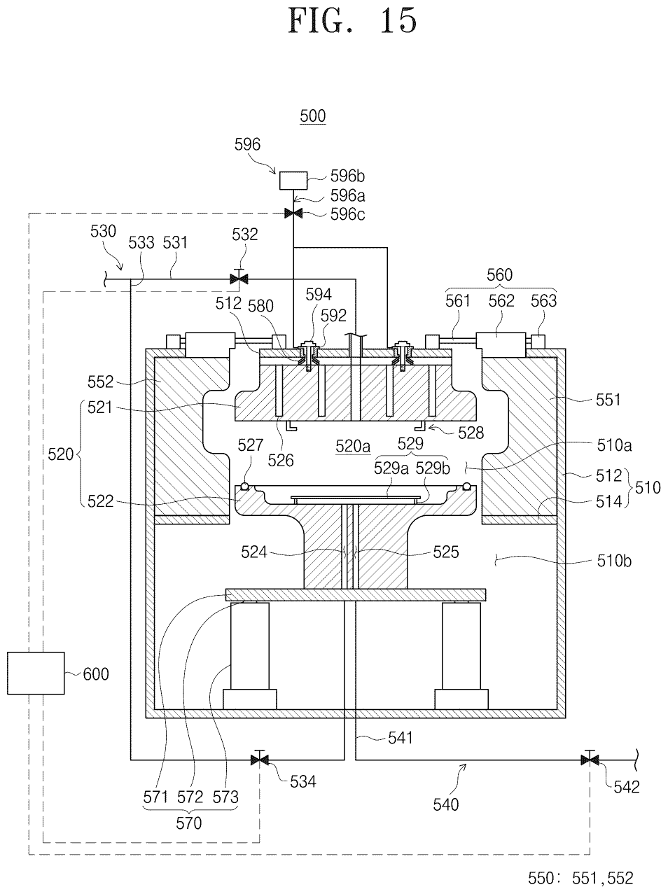

The apparatus of processing a substrate can perform an unloading step (S590). Referring to FIG. 15, the control unit 30 can instruct the transfer chamber 300 to unload the substrate W out of the processing space 520a. The substrate W may have undergone the drying process in step S550. The transfer chamber 300 can unload the substrate W out of the processing chamber 520a in accordance with the instruction of the control unit 600.

In the example described above, in the clamping and particle-removing step S540, clamping by the clamping unit 550 and removing particles by the particle removal unit 590 are simultaneously performed. That is, it was described that the particle removal unit 590 removes particles around the damping unit 580 immediately before the substrate W is processed. However, alternatively, removable of particles may be performed continuously from the sealing step S530 to the clamping and particle-removing step 540 or may be continuously performed from before the sealing step S530.

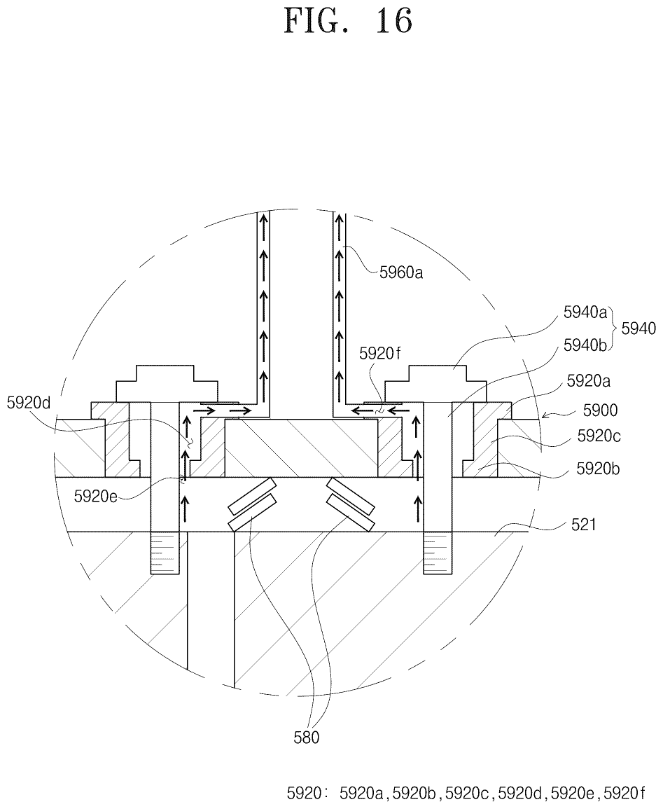

FIG. 16 is a view showing a particle removal unit according to another embodiment of the present disclosure.

A particle removal unit 5900 according to another embodiment of the present disclosure may include a body member 5920, a fixing member 5940, and a suction mechanism 5960. The body member 5920, the fixing member 5940, and the suction mechanism 5960 may be configured equally to the body member 592, the fixing member 594, and the suction mechanism 596 of the particle removal unit 590 described above. The particle removal unit 5900 may be installed on both sides of the damping unit 580. The particle removal unit 5900 can suction particles produced in spaces at both sides of the damping unit 580 by applying negative pressure to the spaces.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

1. An apparatus of processing a substrate, comprising:
a housing having an internal space;
a process chamber disposed in the internal space and defining a processing space in which a substrate is processed-the process chamber including a first chamber body of which a relative position is fixed with respect to the housing and a second chamber body defining the processing chamber by being combined with the first chamber body;
an elevation unit moving the second chamber body with respect to the first chamber body such that the processing space can be switched between a sealed state and an open state;
a damping unit coupled to the first chamber body and absorbing shock that is applied to the first chamber body when relative movement is generated between the first chamber body and the second chamber body; and
a particle removal unit removing particles produced at the damping unit.

2. The apparatus of claim 1, wherein the damping unit is a spring having a hole formed in an up-down direction at a center when seen from above, and
the particle removable unit is provided to apply negative pressure to the hole.

3. The apparatus of claim 1, wherein a plurality of damping units is provided, and the particle removable unit is provided at positions corresponding to the damping units, respectively.

4. The apparatus of claim 1, wherein the particle removable unit includes:
a body member having an opening at a lower end and having a suction space communicating with the opening therein; and
a suction mechanism providing negative pressure to the suction space.

5. The apparatus of claim 4, wherein the damping unit is a disc spring, and
a center hole of the disc spring and the opening overlap each other when seen from above.

6. The apparatus of claim 4, wherein the damping unit is fixed to a lower end of the body member and the first chamber body.

7. The apparatus of claim 1, further comprising:
a clamping unit clamping the process chamber when the processing space is in the sealed state; and
a moving unit moving the clamping unit between a clamping position where the process chamber is clamped and an unclamping position where the process chamber is unclamped.

8. The apparatus of claim 7, further comprising:
a liquid supply unit supplying a processing fluid to the processing space; and
a control unit controlling the elevation unit, the particle removal unit, the moving unit, and the fluid supply unit,
wherein the control unit controls the elevation unit, the particle removal unit, the moving unit, and the fluid supply unit to perform:
an opening step of positioning the first chamber body and the second chamber body at an opening position where the processing space is open;
a loading step of loading a substrate into the processing space after the opening step;
sealing step of positioning the first chamber body and the second chamber body at a closed position where the processing space is closed after the loading step;
a processing step of processing the substrate by supplying a processing fluid to the processing space after the sealing step; and
a particle removal step of applying negative pressure to a region where the damping unit is provided by means of the particle removal unit.

9. The apparatus of claim 8, wherein the control unit further controls the particle removal unit and the clamping unit to perform:
a clamping step of clamping the first chamber body and the second chamber body by means of the clamping unit between the sealing step and the processing step; and
the particle removal step during the clamping step.

10. The apparatus of claim 9, wherein the control unit controls the particle removal unit such that the particle removal unit applies negative pressure to the region, where the damping unit is provided, only in the clamping step among the opening step, the loading step, the sealing step, the clamping step, and the processing step.

11. The apparatus of claim 8, wherein the processing fluid is a supercritical fluid.

12.-16. (canceled)

17. An apparatus of processing a substrate, comprising:
a housing having an internal space;
a process chamber disposed in the internal space and defining a processing space in which a substrate is processed-the process chamber including a first chamber body of which a relative position is fixed with respect to the housing and a second chamber body defining the processing chamber by being combined with the first chamber body;
an elevation unit moving one of the first chamber body and the second chamber body such that the processing space can be switched between a sealed state and an open state;
a clamping unit clamping the process chamber when the processing space is in the sealed state;
a moving unit moving the clamping unit between a clamping position where the process chamber is clamped and an unclamping position where the process chamber is unclamped;
a fluid supply unit supplying a processing fluid to the processing space;
a damping unit coupled to the first chamber body and absorbing shock that is applied to the first chamber body when relative movement is generated between the first chamber body and the second chamber body; and
a particle removal unit removing particles produced at the damping unit,
wherein the apparatus further includes a control unit controlling at least one of the elevation unit, the moving unit, the fluid supply unit, or the particle removal unit, wherein the particle removable unit includes:
a body member having an opening at a lower end and having a suction space communicating with the opening therein; and
a suction mechanism providing negative pressure to the suction space,
wherein the damping unit is a disc spring, and
a center hole of the disc spring and the opening overlap each other when seen from above.

18. The apparatus of claim 17, wherein a plurality of damping units is provided and the damping unit is a spring having a hole formed in an up-down direction at a center when seen from above, and
the particle removable unit is provided at positions corresponding to the damping units, respectively, to apply negative pressure to the hole.

19. The apparatus of claim 17, wherein the control unit control the elevation unit, the particle removal unit, the moving unit, and the fluid supply unit to perform:
an opening step of positioning the first chamber body and the second chamber body at an opening position where the processing space is open;
a loading step of loading a substrate into the processing space after the opening step;
sealing step of positioning the first chamber body and the second chamber body at a closed position where the processing space is closed after the loading step;
a processing step of processing the substrate by supplying a supercritical fluid to the processing space after the sealing step; and
a particle removal step of applying negative pressure to a region where the damping unit is provided by means of the particle removal unit.

20. The apparatus of claim 19, wherein a clamping step of clamping the first chamber body and the second chamber body by means of the clamping unit is further performed between the sealing step and the processing step,
the particle removal unit and the clamping unit are controlled such that the particle removal step is performed during the clamping step, and
the particle removal unit is controlled to apply negative pressure to the region where the damping unit is provided only in the clamping step among the opening step, the loading step, the sealing step, the clamping step, and the processing step.
